(19) United States
(12) Patent Application Publication
(10) Pub. No.: US 2026/0011603 A1
(43) Pub. Date: Jan. 8, 2026

(54) BACKSIDE CONTACT WITH TRENCH ON BACKSIDE SUBSTRATE STRUCTURE

(71) Applicant: INTERNATIONAL BUSINESS MACHINES CORPORATION, ARMONK, NY (US)

(72) Inventors: Xiaoming Yang, Clifton Park, NY (US); Reinaldo Vega, Mahopac, NY (US); Ruilong Xie, Niskayuna, NY (US)

(21) Appl. No.: 18/764,071

(22) Filed: Jul. 3, 2024

(51) Int. Cl. H01L 21/768; H01L 23/522; H01L 27/06; H01L 29/06; H01L 29/40; H01L 29/417; H01L 29/423; H01L 29/66; H01L 29/775; H01L 29/786

(52) U.S. Cl. CPC H01L 21/76877; H01L 21/76831; H10D 62/116; H10D 64/01; H10D 64/257; H10D 84/40; H01L 23/5226; H10D 30/014; H10D 30/43; H10D 30/6735; H10D 30/6757; H10D 62/121

(57) ABSTRACT

A semiconductor device includes a logic device including a first portion of a first substrate extending vertically below a first source/drain region, a second portion of the first substrate extending vertically below a second source/drain region, a first shallow trench isolation (STI) extending vertically and isolating the first portion of the first substrate and the second portion of the first substrate, a backside power delivery network (BSPDN) below the logic device, a first dielectric layer extending vertically through sidewalls of a backside contact. The first dielectric layer isolates the backside contact from the first portion of the first substrate and the second portion of the first substrate.

### BACKGROUND

### Technical Field

The present disclosure generally relates to semiconductors, and more particularly, to semiconductors with backside contact without substrate recession structure, and methods of creation thereof.

### Description of Related Art

The relentless miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip.

### SUMMARY

According to an embodiment, a semiconductor device includes a logic device including a first portion of a first substrate extending vertically below a first source/drain region, a second portion of the first substrate extending vertically below a second source/drain region, a first shallow trench isolation (STI) extending vertically and isolating the first portion of the first substrate and the second portion of the first substrate, a backside power delivery network (BSPDN) below the logic device, a first dielectric layer extending vertically through sidewalls of a backside contact. The first dielectric layer isolates the backside contact from the first portion of the first substrate and the second portion of the first substrate.

In one embodiment, the backside contact is located between the first portion of the first substrate and the second portion of the first substrate, and the backside contact electrically connects a frontside of the logic device to the backside of the logic device.

In one embodiment, the first dielectric layer isolates the backside contact from direct contact with the first source/drain region and the second source/drain region.

In one embodiment, the first dielectric layer isolates the backside contact from contact with the first STI and the first substrate.

In one embodiment, the semiconductor device includes a passive device including a first portion of a second substrate extending vertically below an N-type doped region, a second portion of the second substrate extending vertically below a P-type doped region, a third portion of the second substrate extending horizontally and covering a backside of the passive device, and a second STI extending vertically and isolating the first portion of the second substrate and the second portion of the second substrate.

In one embodiment, the first portion of the first substrate, the second portion of the first substrate, the first portion of the second substrate, and the second portion of the second substrate are made of a same material and are coplanar and have a same height.

In one embodiment, the first STI and the second STI are made of a same material and are coplanar and have a same height.

In one embodiment, the first portion of the first substrate is an N-type well, and the second portion of the first substrate is a P-type well.

According to an embodiment, a method for fabrication of a semiconductor device includes forming a logic device including forming a first portion of a first substrate extended vertically below a first source/drain region, forming a second portion of the first substrate extended vertically below a second source/drain region, isolating the first portion of the first substrate and the second portion of the first substrate by a first shallow trench isolation (STI), forming a backside power delivery network (BSPDN) below the logic device, forming a first dielectric layer extending vertically through sidewalls of a backside contact, and isolating the backside contact from a direct contact with the first portion of the first substrate and the second portion of the first substrate by the first dielectric layer.

In one embodiment, the method includes establishing an electrical connection between a frontside of the logic device to the backside of the logic device by the backside contact. The backside contact is located between the first portion of the first substrate and the second portion of the second substrate.

In one embodiment, the method includes isolating the backside contact from direct contact with the first source/drain region and the second source/drain region by the first dielectric layer.

In one embodiment, the method includes isolating the backside from contact with the first STI and the first substrate via the first dielectric layer.

In one embodiment, the method includes forming a passive device including forming a first portion of a second substrate extended vertically below an N-type doped region, forming a second portion of the second substrate extended vertically below a P-type doped region, forming a third portion of the second substrate extended horizontally and covering a backside of the passive device, and isolating the first portion of the second substrate and the second portion of the second substrate by a second STI.

In one embodiment, the first portion of the first substrate, the second portion of the first substrate, the first portion of the second substrate, and the second portion of the second substrate are made of a same material and are coplanar and have a same height.

In one embodiment, the first STI and the second STI are made of a same material and are coplanar and have a same height.

In one embodiment, the first portion of the first substrate is an N-type well, and the second portion of the first substrate is a P-type well.

According to an embodiment, a semiconductor device includes a logic device including a backside contact electrically connecting a frontside of the logic device to a backside of the logic device, and a dielectric layer over sidewalls of the backside contact. The dielectric layer isolates the backside contact from direct contact with a first source/drain region, a second source/drain region, a first shallow trench isolation (STI), and a first substrate of the logic device. The semiconductor device includes a passive device formed over a second substrate. The first substrate and the second substrate are coplanar.

In one embodiment, the logic device further includes a first portion of the first substrate extending vertically below a first source/drain region, a second portion of the first substrate extending vertically below a second source/drain region, and a backside power delivery network (BSPDN) below the logic device.

In one embodiment, the first portion of the first substrate is an N-type well, and the second portion of the first substrate is a P-type well.

In one embodiment, the passive device further includes a first portion of the second substrate extending vertically below an N-type doped region. a second portion of the second substrate extending vertically below a P-type doped region. a third portion of the second substrate extending horizontally and covering a backside of the passive device, and a second STI extending vertically and isolating the first portion of the second substrate and the second portion of the second substrate.

In one embodiment, the first STI and the second STI are made of a same material and are coplanar and have a same height.

According to an embodiment, a method for fabrication of a semiconductor device includes forming a logic device including establishing an electrical connection between a frontside of the logic device and a backside of the logic device with a backside contact, and forming a dielectric layer over sidewalls of the backside contact, isolating the backside contact from direct contact with a first source/drain region, a second source/drain region, a first shallow trench isolation (STI) and a first substrate via the dielectric layer and forming a passive device over a second substrate. The first substrate and the second substrate are coplanar.

In one embodiment, the method includes forming a first portion of the first substrate extending vertically below the first source/drain region, forming a second portion of the first substrate extending vertically below the second source/drain region, and forming a backside power delivery network (BSPDN) below the logic device.

In one embodiment, the method includes forming a passive device including forming a first portion of the second substrate extending vertically below an N-type doped region, forming a second portion of the second substrate extending vertically below a P-type doped region, forming a third portion of the second substrate extending horizontally over the backside of the passive device, and isolating the first portion of the second substrate and the second portion of the second substrate by a second STI.

In one embodiment, the first STI and the second STI are made of a same material and are coplanar and have a same height.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1B illustrate a logic device of a semiconductor device, in accordance with some embodiments.

FIG. 1C illustrates a passive device of a semiconductor device, in accordance with some embodiments.

FIGS. 2A-2B illustrate a semiconductor device after the formation of the metal gates, consistent with an illustrative embodiment.

FIG. 2C illustrates a top view of the logic device after the formation of the metal gates.

FIGS. 3A-3B illustrate a semiconductor device after the patterning of the frontside contacts, in accordance with some embodiments.

FIG. 3C illustrates a top view of the logic device after the patterning of the frontside contacts.

FIGS. 4A-4B illustrate a semiconductor device after metallization of the frontside contacts, in accordance with some embodiments.

FIG. 4C illustrates a top view of the logic device after the metallization of the frontside contacts.

FIGS. 5A-5B illustrate a semiconductor device after formation of the additional interlayer dielectric, in accordance with some embodiments.

FIG. 5C illustrates a top view of the logic device after the formation of the interlayer dielectric.

FIGS. 6A-6B illustrate a semiconductor device after the formation of the vias and the M1 track, in accordance with some embodiments.

FIG. 6C illustrates a top view of the logic device after the formation of the vias and the M1 track.

FIGS. 7A-7B illustrate a semiconductor device after the formation of the BEOL, in accordance with some embodiments.

FIG. 7C illustrates a top view of the logic device after the formation of the BEOL.

FIGS. 8A-8B illustrate a semiconductor device after the carrier wafer bonding, in accordance with some embodiments.

FIG. 8C illustrates a top view of the logic device after the carrier wafer bonding.

FIGS. 9A-9B illustrate a semiconductor device after the wafer flip and grinding, in accordance with some embodiments.

FIG. 9C illustrates a top view of the logic device after the wafer flip.

FIGS. 10A-10B illustrate a semiconductor device after the removal of the first substrate, in accordance with some embodiments.

FIG. 10C illustrates a top view of the logic device after the removal of the first substrate.

FIGS. 11A-11B illustrate a semiconductor device after the after the removal of the etch stop layer, in accordance with some embodiments.

FIG. 11C illustrates a top view of the logic device after the removal of the etch stop layer.

FIGS. 12A-12C illustrate a semiconductor device after the formation of the backside contact and the dielectric layer, in accordance with some embodiments.

FIGS. 13A-13C illustrate a semiconductor device after the formation of the backside metal lines, in accordance with some embodiments.

FIG. 14 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

The concepts herein relate to semiconductor devices with backside power delivery network (BSPDN). In the existing fully depleted bulk process (FVBP), an aspect is the silicon thickness remaining under various regions of the semiconductor device. Specifically, under the source/drain regions, the silicon thickness can be as low as 30 nanometers. This thin silicon layer is one of the factors in determining the electrical characteristics and overall performance of the semiconductor device. The reduced silicon thickness under the source/drain regions can lead to increased resistance, which directly impacts the efficiency and functionality of the semiconductor device.

Under the shallow trench isolation (STI) areas of the passive components, the silicon thickness can be around 50 nanometers. This thicker layer, while beneficial in some respects, introduces challenges in maintaining consistent performance across different regions of the chip. The variability in silicon thickness can lead to discrepancies in electrical characteristics, making it difficult to achieve uniform performance. This inconsistency is particularly problematic for high-precision applications where every nanometer of silicon can affect the behavior of the circuit.

The impact on narrow width resistance (NWres) models can be significant. The NWres models are used to accurately predict the resistance of narrow width transistors, which are commonly used in modern semiconductor designs. The variation in silicon thickness under the source/drain regions and STI can cause deviations in the expected resistance values, leading to potential performance issues. High resistance in such models can result in slower signal propagation, increased power consumption, and reduced overall efficiency of the integrated circuit. Moreover, the high resistance in other passive component models further exacerbates these issues. Passive components such as resistors, capacitors, and inductors rely on precise resistance values to function correctly. Any deviation from the expected resistance can lead to malfunction or suboptimal performance of the entire chip. High resistance in passive components can also cause signal distortion, noise, and other undesirable effects that degrade the quality and reliability of the semiconductor device.

Another concern associated with the resistance issues is the potential for latch-up. Latch-up is a condition where a parasitic structure within the semiconductor device forms a low-impedance path, leading to a short circuit. This phenomenon is particularly problematic at high operating frequencies, where the rapid switching of transistors can trigger latch-up events. Latch-up can cause permanent damage to the semiconductor device, leading to failure and necessitating costly repairs or replacements. The risk of latch-up under high-frequency operation underscores the importance of addressing the silicon thickness variability in FVBP.

In view of the above considerations, disclosed is a semiconductor device with backside contact without the substrate recession. The disclosed semiconductor device ensures uniform silicon thickness across different regions of the chip, to maintain consistent performance and prevent the latch-up through precisely controlling thickness of the silicon substrate on the backside of the semiconductor device. By minimizing the risk of latch-up and, the disclosed semiconductor device can meet the demands of modern electronic applications.

Accordingly, the teachings herein provide methods and systems of semiconductor device formation with backside contact without substrate recession. The techniques described herein may be implemented in a number of ways. Example implementations are provided below with reference to the following figures.

### Example Semiconductor Device with Backside Contact Without Substrate Recession Structure

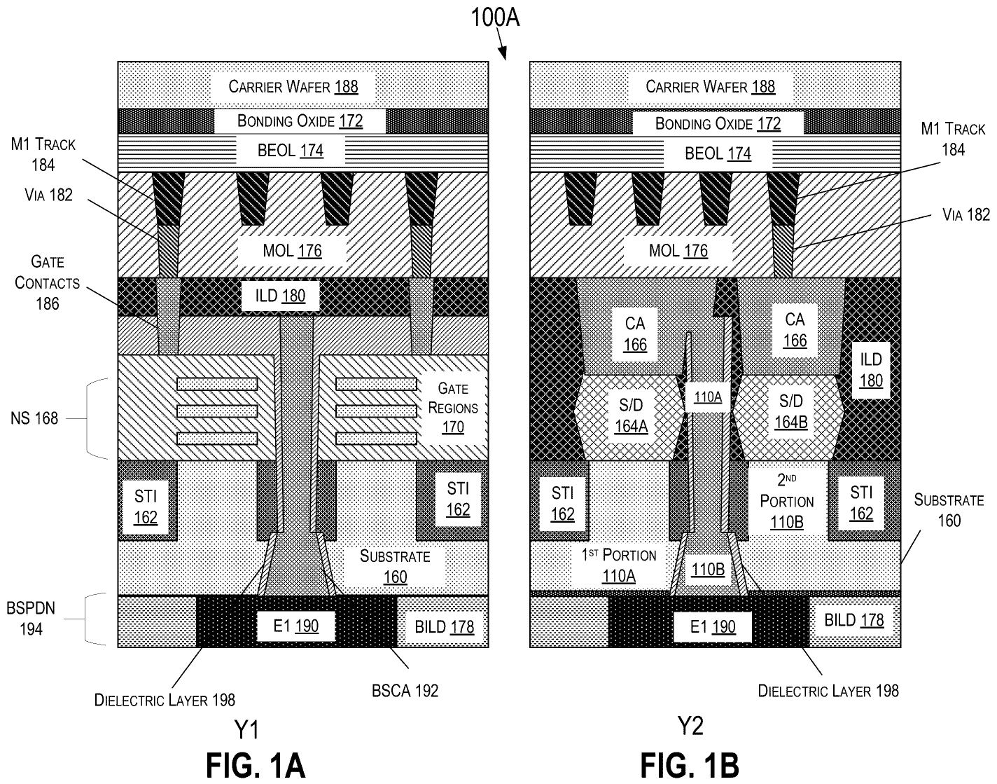

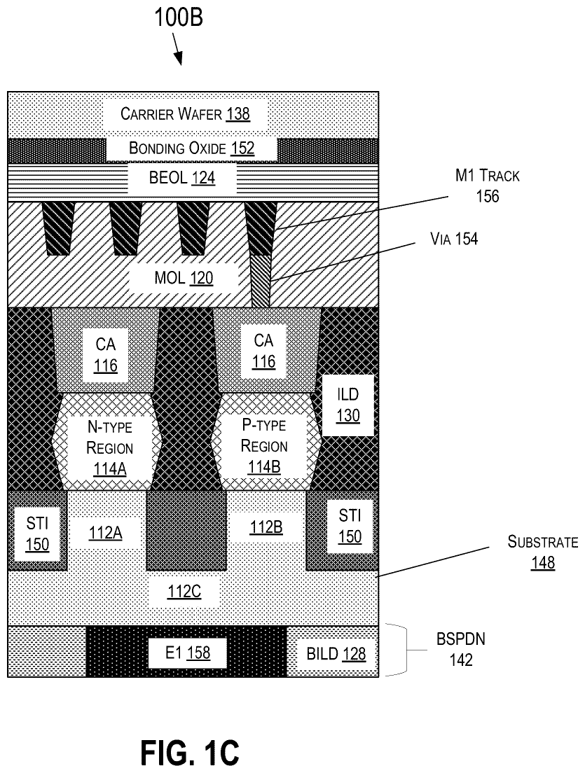

Reference now is made to FIGS. 1A-1C, which are simplified cross-sections view of a semiconductor device, consistent with an illustrative embodiment. In various embodiments, the semiconductor device includes a logic device 100A and a passive device 100B. While for the sake of simplicity, the logic device 100A and the passive device 100B are depicted separately, it should be noted that the logic device 100A and the passive device 100B can be integrated on a same semiconductor device adjacent to each other.

Referring to FIGS. 1A-1B, the logic device of the semiconductor device is illustrated. The logic device 100A, which can be a transistor, can include a substrate 160, a first shallow trench isolation, STI 162, a first source/drain region, S/D 164A, a second source/drain region, S/D 164B, source/drain contacts, CA 166, nanosheet gates, NS 168, gate regions 170, a bonding oxide 172, back end of line, BEOL 174, middle of line, MOL 176, a bottom interlayer dielectric, BILD 178, interlayer dielectric, ILD 180, a via 182, a metal line, M1 track 184, gate contacts 186, a carrier wafer 188, a backside metal line, E1 190, a backside contact, BSCA 192, backside power delivery network, BSPDN 194, and a dielectric layer 198.

The substrate 160 can be composed of silicon and can provide the mechanical support necessary for the integrated circuit's construction. In some embodiments, the substrate 160 can include a first portion 110A extending vertically below the S/D 164A, a second portion 110B extending vertically below the S/D 164B.

The STI 162 can be used to electrically isolate individual components, e.g., the first portion 110A of the substrate 160 and the second portion 110B of the substrate 160, and other components on a passive device 100B. The STI 162 can be made by etching narrow trenches into the substrate 160 and then filling these trenches with an insulating material, usually silicon dioxide. This process can prevent electrical interference between adjacent components, which can help maintain the integrity of signals and ensuring proper device functionality. In some embodiments, the STI can be extended vertically and isolate the first portion 110A of the substrate 160 and the second portion 110B of the substrate 160.

Generally, the source/drain regions, such as the S/D 164A and S/D 164B, are salient components that play relevant roles in the semiconductor device's operation. In various embodiments, the S/D 164A and S/D 164B are region within the semiconductor material, e.g., the semiconductor device, where the current flows in and out of the semiconductor device. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

The CA 166, located over the S/D 164A and S/D 164B, can establish connections between the S/D 164A and S/D 164B and the MOL 176 and the BEOL 174. The CA 166 can ensure efficient electrical routing and connectivity within the logic device 100A. The fabrication of the CA 166 can involve lithography and etching processes to define the contact area. The CA 166 can be made using conductive materials such as copper (Cu) or tungsten (W).

The NS 168 can be alternating, vertically-oriented sheets, which can drive current in a small footprint area. In some embodiments, NS 168 includes silicon nanowires. In other words,

NS 168 includes three-dimensional structures in the gate, which are extended from a source region towards a drain region.

In various embodiments, the gate regions 170 serve as control elements that regulate the flow of current through the logic device 100A. The gate regions 170 can be composed of a conductive material. The gate regions 170 can control the flow of electric current between the source and drain regions. In addition to acting as a switch, modulating the gate voltage can enable the gate regions 170 to control the current flowing through the channel region, resulting in amplified output signals.

In an embodiment, the gate regions 170 can enable the implementation of Boolean logic operations, such as AND, OR, and NOT, by controlling the flow of current based on the input voltages. In some embodiments, the gate regions 170, along with other active device components, can facilitate the miniaturization and integration of electronic circuits. The ability to control the channel region's conductivity through the gate voltage allows for compact and highly efficient circuit designs.

In several embodiments, the BILD 178 can provide structural support to the semiconductor device by maintaining the mechanical integrity and stability of the logic device 100A. The BILD 178 can further help prevent the warping, bending, or cracking of the substrate, particularly during the manufacturing process or subsequent handling. The BILD 178 can ensure that the logic device 100A remains mechanically robust and maintains its dimensional stability.

In an embodiment, the BILD 178 can also serve as a planarization layer in the logic device 100A fabrication process. As various layers are deposited and patterned on the front side of the logic device 100A, irregularities or topographic variations may arise. The BILD 178 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 178 can contribute to improved overall semiconductor device performance. In several embodiments, BILD 178 can facilitate wafer-level testing of the semiconductor device. By providing electrical isolation between the active regions and the backside contact, individual active device or elements on the logic device 100A can be electrically accessed and tested without interference from neighboring devices or components. This enables efficient and accurate wafer-level testing, ensuring quality control during semiconductor manufacturing.

The ILD 180 can be a layer of insulating material to electrically isolate and provide mechanical support between different layers of conducting and active components. The ILD 180 can enable efficient signal transmission, reduce crosstalk, and ensure the proper functioning of the logic device 100A. In an embodiment, the ILD 180 can electrically isolate adjacent conducting layers or active components in the logic device 100A. By providing insulation between different layers, the ILD 180 can prevent electrical shorts, reduce (e.g., minimize) leakage current, and ensure that signals are directed only along the desired pathways. In some embodiments, the ILD 180 can help reduce parasitic capacitance between adjacent metal interconnects or active devices and provide mechanical support to the active device's structure.

The bonding oxide 172 can be employed to facilitate the bonding of different layers or wafers, i.e., the logic device 100A to the carrier wafer 188. The bonding oxide 172 can be composed of silicon dioxide and can act as an intermediary that ensures strong adhesion between the bonded surfaces. In some embodiments, the bonding oxide 172 can serve as an insulating layer, preventing electrical conduction between the bonded layers.

The BEOL 174 can include metal interconnects and other structures on the upper layers of a logic device 100A to form a network of connections that link various components of the logic device 100A.

The MOL 176 can connect the BEOL 174 to the other components of the logic device 100A and include contacts and local interconnects that connect the transistor to the first level of metal interconnects. In some embodiments, the MOL 176 can include contact vias, such as via 182, and the M1 track 184. The via 182 can be an opening or hole in the logic device 100A that allows for vertical electrical connections between different metal layers. The via 182 can be used to create a multi-layer interconnect structure. The M1 track 184 can be the first layer of metal interconnects in the logic device 100A, and form the routing paths for electrical signals between different components on the logic device 100A.

The gate contacts 186 are the conductive connections that link the gate electrodes of the logic device 100A to the interconnect network. The gate contacts 186 can be formed using materials such as tungsten or copper, deposited into contact holes etched in the insulating layers.

The carrier wafer 188 can be used as a temporary support for handling the logic device 100A during semiconductor processing and provide mechanical stability and protection during various fabrication steps, such as thinning, bonding, and dicing. The carrier wafer 188 can be eventually removed, leaving the logic device 100A ready for packaging. The E1 190 can be a metal interconnect formed on the backside of a logic device 100A for power distribution, signal routing, or thermal management.

The BSCA 192 is a region on the backside of the logic device 100A where electrical connections are made. By establishing the electrical contacts, the BSCA 192 can ensure the proper functioning of the logic device 100A and facilitates electrical signal transmission. The BSCA 192 can serve as a thermal interface between the logic device 100A and a heat sink or other cooling mechanisms. By establishing direct contact with the substrate, the BSCA 192 can conduct the heat away from the logic device 100A, and contribute to improved thermal dissipation. In some embodiments, the BSCA 192 can help mitigate parasitic effects, such as substrate coupling or substrate noise, from the logic device 100A. In further embodiments, the BSCA 192 can allow for increased integration density in the logic device 100A.

The BSPDN 194 can be a network of metal interconnects on the backside of a logic device 100A that provides power to the logic device 100A. The BSPDN 194 can help to distribute power more efficiently and reduce voltage drops across the logic device 100A.

In some embodiments, the first dielectric layer 198 can isolate the BSCA 192 from direct contact with the S/D 164A and S/D 164B. In some embodiments, the first dielectric layer 198 can isolate the BSCA 192 from contact with the STI 162 and the substrate 160.

The first dielectric layer 198 can be formed over the sidewalls of the BSCA 192 is used to insulate and protect the contact structures from electrical interference and physical damage. The first dielectric layer 198 can be composed of materials such as silicon dioxide or silicon nitride, to ensure that the backside contacts maintain their electrical integrity and do not short with other structures.

In some embodiments, the BSCA 192 can be extended vertically within the third portion 100C of the substrate 160 and be located between the first portion 110A of the substrate 160 and the second portion 110B of the substrate 160. In some embodiments, the BSCA 192 can electrically connect the frontside of the logic device 100A to the backside of the logic device 100A.

Reference is now made to FIG. 1C, where a passive device of a semiconductor device is illustrated, according to some embodiments. In some embodiments, the passive device 100B can include an N-type doped region 114A, a P-type doped region 114B, frontside contacts, CA 116, MOL 120, BEOL 124, BILD 128, ILD 130, a carrier wafer 138, BSPDN 142, a substrate 148, a second shallow trench isolation, STI 150, a bonding oxide 152, a via 154, a metal line, M1 track 156, a backside metal line, E1 158.

The substrate 148 can include a first portion 112A extending vertically below the N-type doped region 114A, a second portion 112B extending vertically below the P-type doped region 114B, and a third portion 112C extending horizontally and covering a backside of the passive device 100B.

In some embodiments, the first portion 112A can be an N-type doped, and the second portion 112B can be P-type doped to form a p-n junction of the passive device 100B. The p-n junction can control the flow of electrical current within the passive device 100B. The p-n junction can be created by doping two adjacent regions of the passive device 100B, one with a type P dopant, which introduces an excess of positive charge carriers (holes), and the other with a type N dopant, which introduces an excess of negative charge carriers (electrons). At the interface between the P and N regions, a depletion region forms due to the diffusion of electrons from the N region into the P region and the diffusion of holes in the opposite direction. Such a diffusion process continues until the electric field created by the accumulation of charge at the junction balances the diffusion forces, resulting in a zone depleted of free charge carriers. In its natural state, the p-n junction allows current to flow more easily in one direction than in the opposite. When forward-biased, i.e., positive voltage applied to the P side relative to the N side, the depletion region narrows, lowering the barrier for charge carriers to move across the junction, and allowing current to flow through the device. Conversely, when reverse-biased, i.e., negative voltage applied to the P side, the depletion region widens, increasing the barrier for charge movement, and significantly reducing the flow of current.

The CA 116, located over the N-type doped region 114A and the P-type doped region 114B, can establish connections between the N-type doped region 114A and the P-type doped region 114B and the BEOL 124. The CA 116 can ensure efficient electrical routing and connectivity within the passive device 100B. The fabrication of the CA 116 can involve lithography and etching processes to define the contact area. The CA 116 can be made using conductive materials such as copper (Cu) or tungsten (W).

The BEOL 124 can include metal interconnects and other structures on the upper layers of a passive device 100B to form a network of connections that link various components of the passive device 100B.

The MOL 120 can connect the BEOL 124 to the other components of the passive device 100B and include contacts and local interconnects that connect the transistor to the first level of metal interconnects. In some embodiments, the MOL 120 can include contact vias, such as via 154, and the M1 track 156. The via 154 can be an opening or hole in the passive device 100B that allows for vertical electrical connections between different metal layers. The via 154 can be used to create a multi-layer interconnect structure. The M1 track 156 can be the first layer of metal interconnects in the logic device 100A, and form the routing paths for electrical signals between different components on the passive device 100B.

In several embodiments, the BILD 128 can provide structural support to the passive device 100B by maintaining the mechanical integrity and stability of the passive device 100B. The BILD 128 can further help prevent the warping, bending, or cracking of the substrate, particularly during the manufacturing process or subsequent handling. The BILD 128 can ensure that the passive device 100B remains mechanically robust and maintains its dimensional stability.

In an embodiment, the BILD 128 can also serve as a planarization layer in the passive device 100B fabrication process. As various layers are deposited and patterned on the front side of the passive device 100B, irregularities or topographic variations may arise. The BILD 128 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 128 can contribute to improved overall passive device performance. In several embodiments, BILD 128 can facilitate wafer-level testing of the passive device 100B. By providing electrical isolation between the active regions and the backside contact, individual passive device or elements on the passive device 100B can be electrically accessed and tested without interference from neighboring devices or components. This enables efficient and accurate wafer-level testing, ensuring quality control during semiconductor manufacturing.

The ILD 130 can be a layer of insulating material to electrically isolate and provide mechanical support between different layers of conducting and active components. The ILD 130 can enable efficient signal transmission, reduce crosstalk, and ensure the proper functioning of the passive device 100B. In an embodiment, the ILD 130 can electrically isolate adjacent conducting layers or active components in the passive device 100B. By providing insulation between different layers, the ILD 130 can prevent electrical shorts, reduce (e.g., minimize) leakage current, and ensure that signals are directed only along the desired pathways. In some embodiments, the ILD 130 can help reduce parasitic capacitance between adjacent metal interconnects or active devices and provide mechanical support to the passive device's structure.

The STI 150 helps prevent electrical crosstalk and interference between adjacent components, allowing for the proper functioning of integrated circuits. The STI 150 can be an insulating material or layer used to isolate and provide electrical insulation between the passive device's various regions and components, and to prevent unwanted electrical contact between such regions and components, ensuring the proper functioning and integrity of the passive device 100B. In various embodiments, the STI 150 can act as a protective layer, shielding the active regions of the passive device from external contaminants, moisture, and mechanical stress. The STI 150 can further help prevent physical damage, such as scratches or particle contamination, which could adversely affect passive device performance. Additionally, the STI 150 can act as a barrier against moisture ingress, which can cause corrosion and degradation of the passive device's components.

The STI 150 can be extended vertically and isolate the first portion 112A of the substrate 148 and the second portion 112B of the substrate 148.

It should be noted that, since the logic device 100A and the passive device 100B can be adjacent to each other on the semiconductor device, the logic device 100A and the passive device 100B can share a common carrier wafer, BSPDN, substrate, STI, bonding oxide, and backside metal line. In other words, in some embodiments, the carrier wafer 138 can be the same as the carrier wafer 188. Similarly, in some embodiments, the BSPDN 142 can be the same as the BSPDN 194. Similarly, in some embodiments, the substrate 160 can be the same as the substrate 148. Similarly, in some embodiments, the STI 150 can be the same as the STI 162. Similarly, in some embodiments, the bonding oxide 152 can be the same as the bonding oxide 172. Similarly, in some embodiments, the E1 158 can be the same as the E1 190.

Further, in some embodiments, the first portion 110A and the second portion 110B of the substrate 160 are made of a same material and are coplanar and have a same height as the first portion 112A and the second portion 112B of the substrate 148. In some embodiments, the STI 150 and the STI 162 are made of a same material and are coplanar and have a same height.

### Example Act of Fabrication of Semiconductor Device with Backside Contact Without Substrate Recession

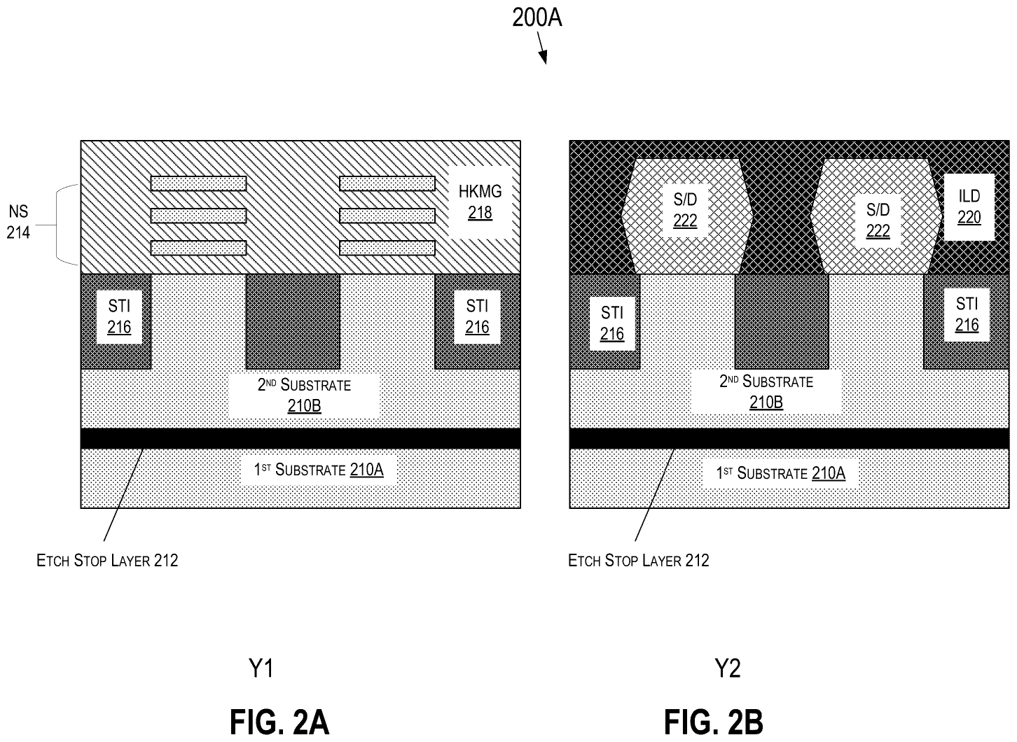

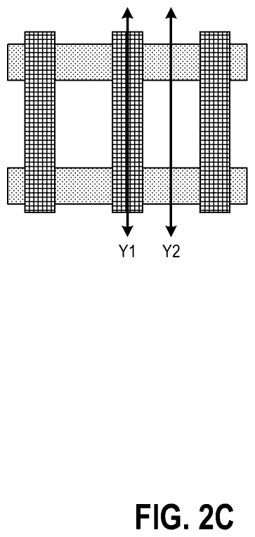

With the foregoing description of an example semiconductor device, it may be helpful to discuss an example process of manufacturing the same. To that end, FIGS. 2-17 illustrate various acts in the manufacture of a semiconductor device, consistent with illustrative embodiments. Figures denoted by A show the acts of fabrication of the logic device in Y1 cross-section, figures denoted by B show the acts of fabrication of the logic device in Y2 cross-section, and figures denoted by C illustrate the acts of fabrication of the passive device. Figures denoted by D illustrate top views of the semiconductor device.

Reference now is made to FIGS. 2A-2B, which are simplified cross-section views of a semiconductor device after the formation of the replacement metal gate, in accordance with some embodiments. In some embodiments, once the replacement metal gate (RMG) process is performed, the logic device 200A includes a first substrate 210A, a second substrate 210B, an etch stop layer 212, nanosheet gates, NS 214, STI 216, high-k metal gate, HKMG 218, ILD 220, and source/drain regions, S/D 222.

In the illustrative example depicted in FIGS. 2A-2B, the semiconductor device is depicted as being on silicon as the first substrate 210A and the second substrate 210B, while it will be understood that other types as the first substrate 210A and the second substrate 210B may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 210A and the second substrate 210B can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 212 is formed over the first substrate 210A. The etch stop layer 212 can be a thin layer of material incorporated into the structure of the semiconductor device to provide a selective barrier against etching processes, preventing further removal of underlying materials during fabrication. The etch stop layer 212 can enable precise control over the etching depth and help define the desired device dimensions. The etch stop layer 212 can further provide a stopping point for the etching process, ensuring that specific layers or regions are not etched beyond a certain point, leading to accurate patterning and control of critical features. The etch stop layer 212 can create a distinct separation between different layers or components within the device structure, and prevent the undesired etching of underlying layers or materials, enabling the creation of complex, multi-layered structures with well-defined interfaces and boundaries. In some embodiments, the etch stop layer 212 acts as a protective barrier for sensitive or delicate materials to shield such materials from aggressive etchants, preventing damage or degradation during subsequent fabrication steps.

In some embodiments, prior to forming the etch stop layer 212, the first substrate 210A is prepared by cleaning and removing any impurities or oxide layers. The etch stop layer 208 is deposited onto the first substrate 210A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 212 can then be selectively etched, stopping at a predetermined depth, while protecting the underlying layers. After the etching process, the remaining photoresist can be removed through stripping techniques. While in some embodiments, SiGe is used to form the etch stop layer 212, in some embodiments, silicon nitride (SiN), silicon oxide (SiO2), or silicon oxynitride (SiON) can be used as the etch stop layer 208.

In some embodiments, the NS 214 can be formed by alternating layers of Si layers and SiGe layers, in which sidewalls of the SiGe layers are indented and covered by the inner spacers. The SiGe layers can subsequently be removed and replaced with gate region materials.

In some embodiments, one or more the STI 216 can be made of SiN. The ILD 220 can be made of SiO2. The HKMG 218 can be formed over the logic device 200A. A replacement metal gate (RMG) process can be used to fabricate metal gate electrodes. In some embodiments, RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability. FIG. 2C illustrates a top view of a logic device after the formation of the replacement metal gate.

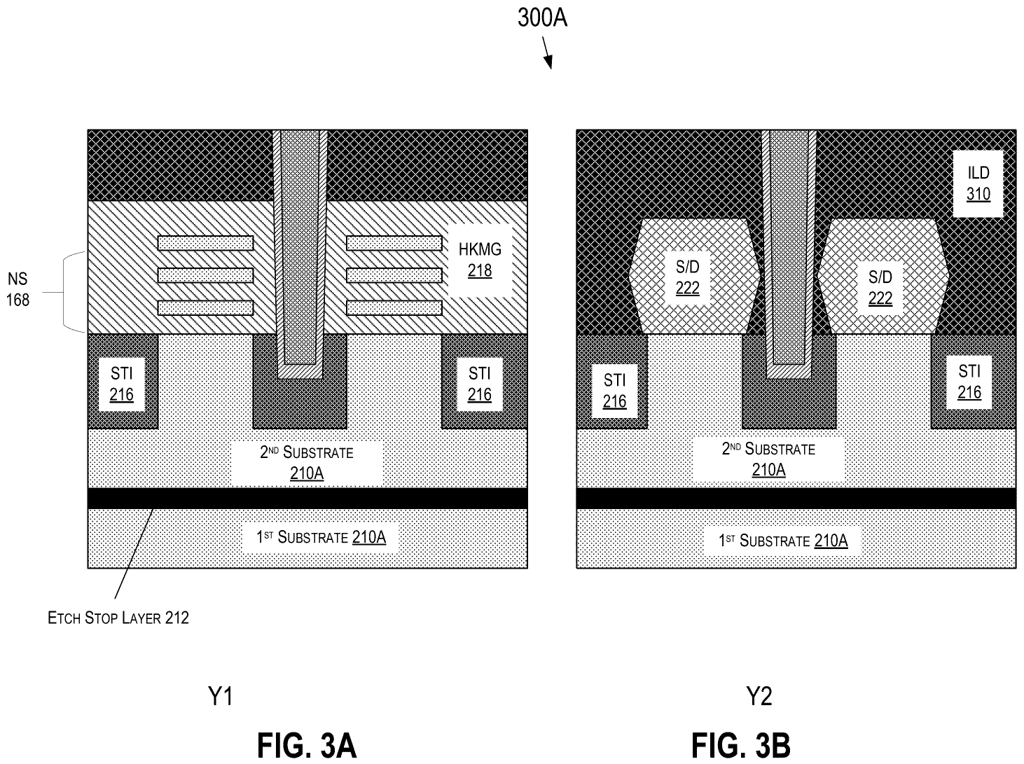

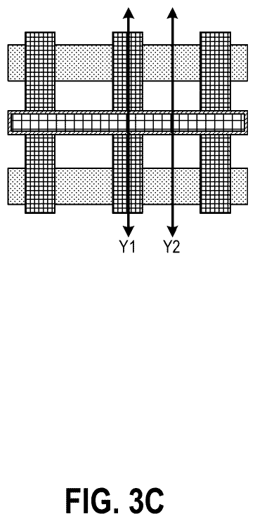

FIGS. 3A-3B illustrate a semiconductor device after the patterning of the frontside contacts, in accordance with some embodiments. In some embodiments, the additional ILD 310 is formed over the logic device 300A and portions of the additional ILD 310, the ILD 220, the HKMG 218, and the STI 216 are removed. FIG. 3C illustrates a top view of the logic device 300A after the patterning of the frontside contacts.

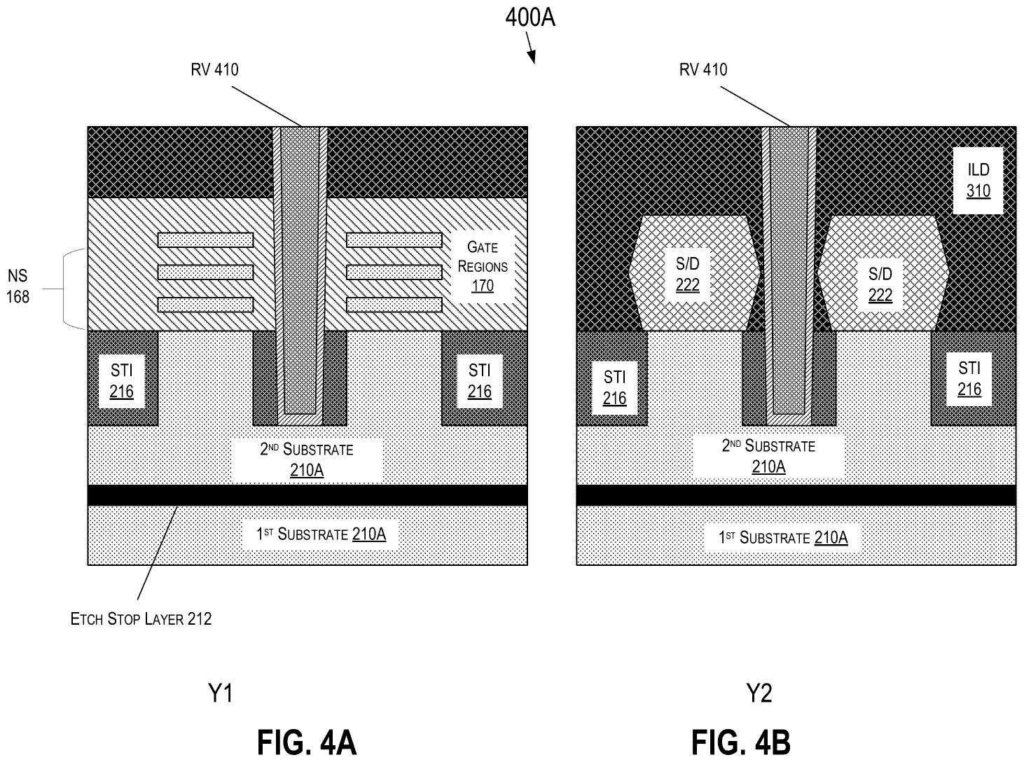

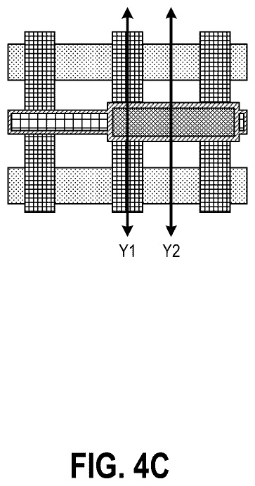

FIGS. 4A-4B illustrate a semiconductor device after the metallization of the frontside contacts, in accordance with some embodiments. In some embodiments, the removed portions of the additional ILD 310, the ILD 220, the HKMG 218, and the STI 216 are filled with a suitable material to form the frontside contacts, RV 410. FIG. 4C illustrates a top view of the logic device 400A after the metallization of the frontside contacts.

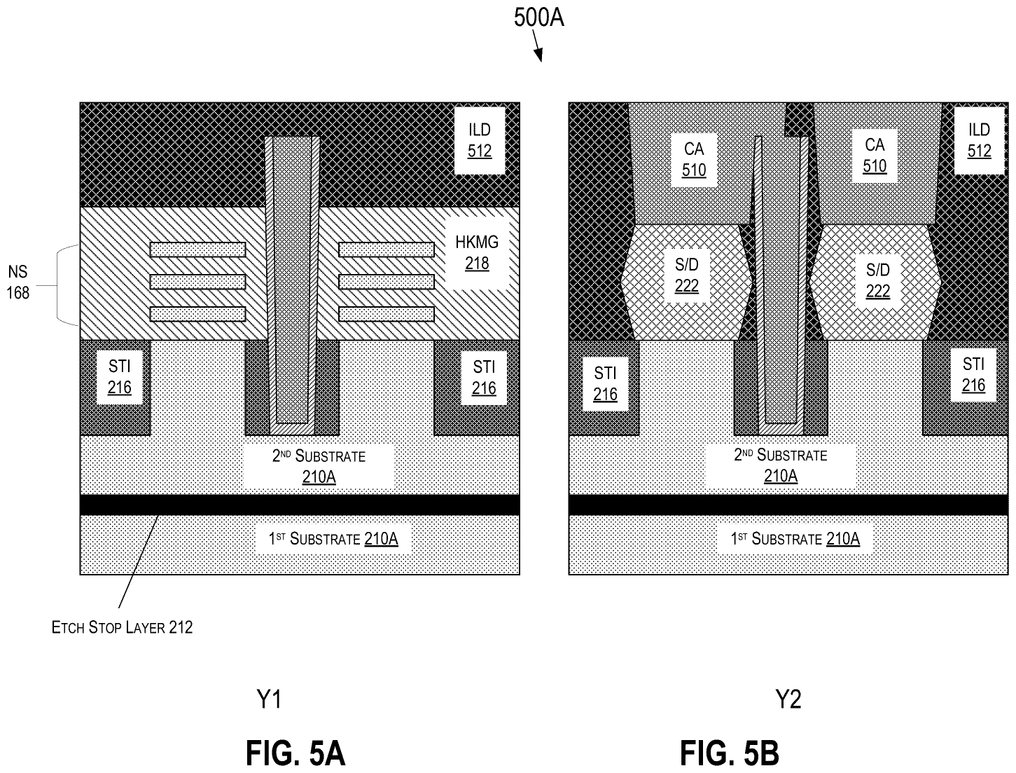

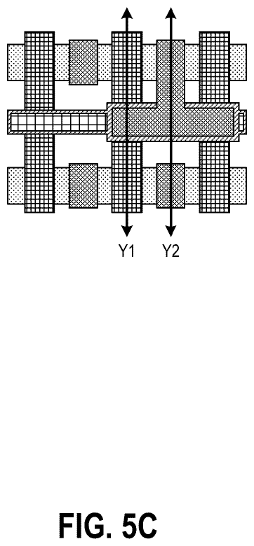

FIGS. 5A-5B illustrate a semiconductor device after the formation of the additional interlayer dielectric, in accordance with some embodiments. In some embodiments, additional layer of ILD 512 can be formed over the logic device 500A, followed by the formation of the source/drain contacts, CA 510, over the source/drain regions. FIG. 5C illustrates a top view of the logic device 500A after the formation of the source/drain contacts.

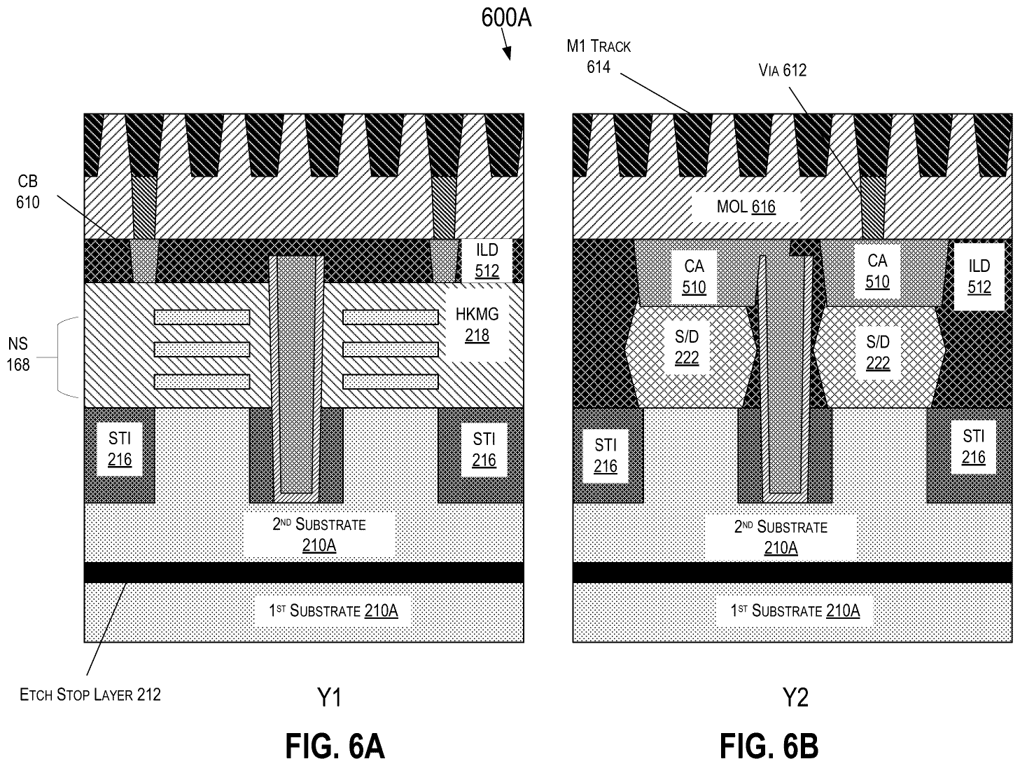

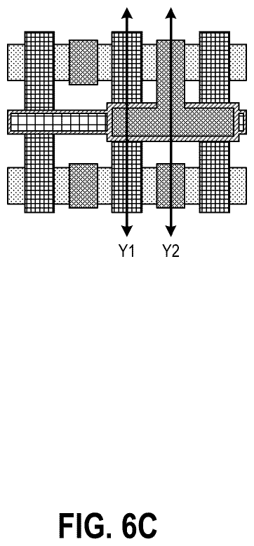

FIGS. 6A-6B illustrate a semiconductor device after the formation of the vias and the M1 track, in accordance with some embodiments. In some embodiments, the gate contacts, CB 610, are formed over the gate regions. MOL process can be performed which can include formation of the set of vias 612 and the M1 track 614 to connect the active region of the logic device 600A to the MOL 616. The set of vias 612 can connect the CB 610 and the CA 510 to the MOL 616. FIG. 6C illustrates a top view of the logic device 600A after the formation of the vias and the M1 track.

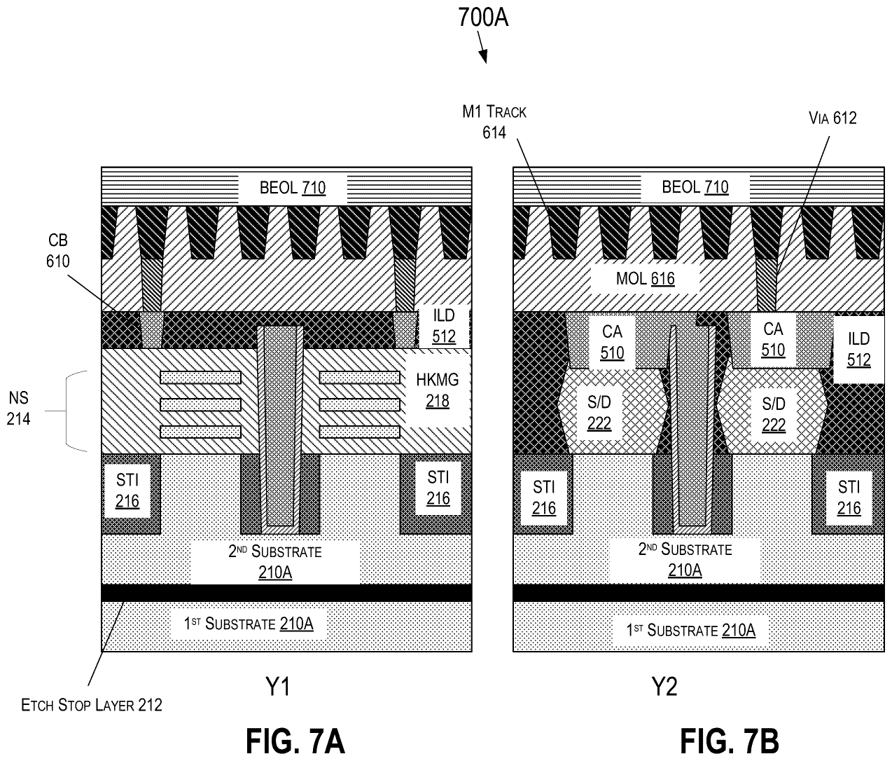

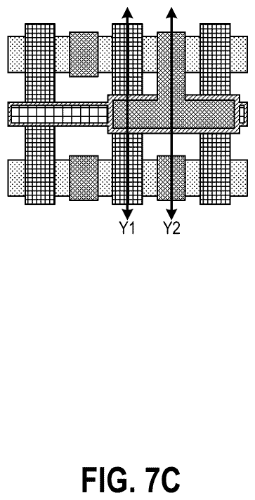

FIGS. 7A-7B illustrate a semiconductor device after the formation of the BEOL, in accordance with some embodiments. In some embodiments, the BEOL 710 is formed over the MOL 616. FIG. 7C illustrates a top view of the logic device 700A after the formation of the BEOL.

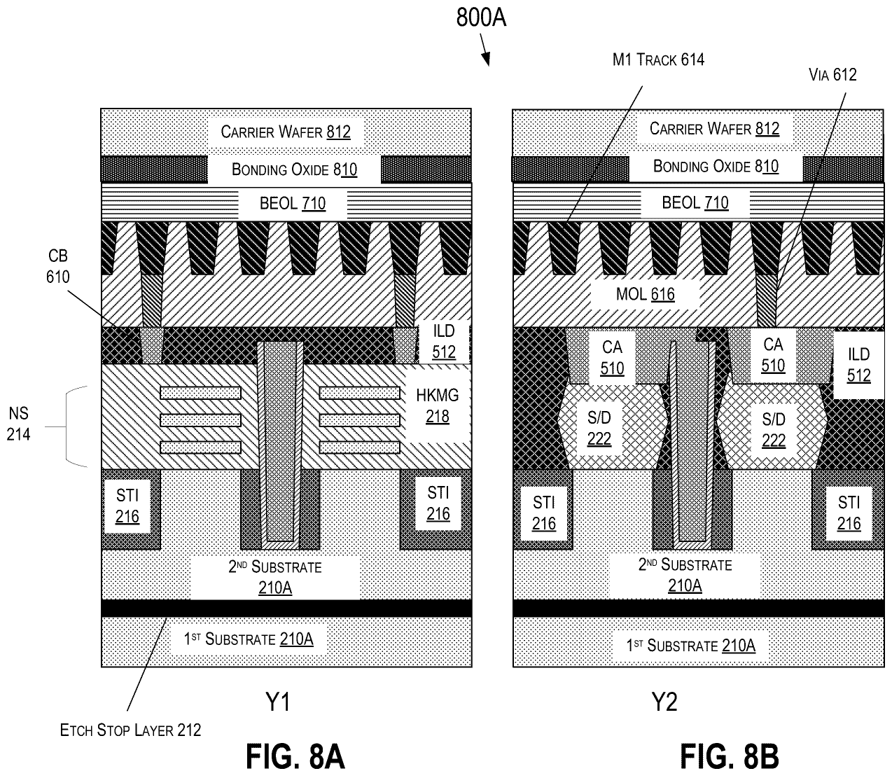

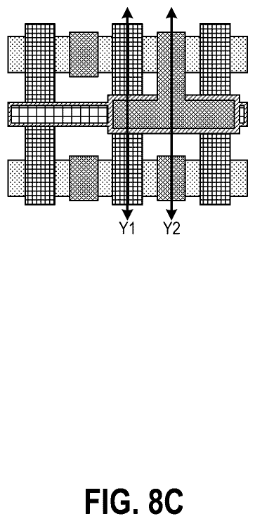

FIGS. 8A-8B illustrate a semiconductor device after the carrier wafer bonding, in accordance with some embodiments. In some embodiments, a bonding oxide 810 is formed over the BEOL 710. A carrier wafer 812 is bonded to the logic device 800A via the bonding oxide 810. In some embodiments, carrier wafer bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices. FIG. 8C illustrates a top view of the logic device 800A after the carrier wafer bonding.

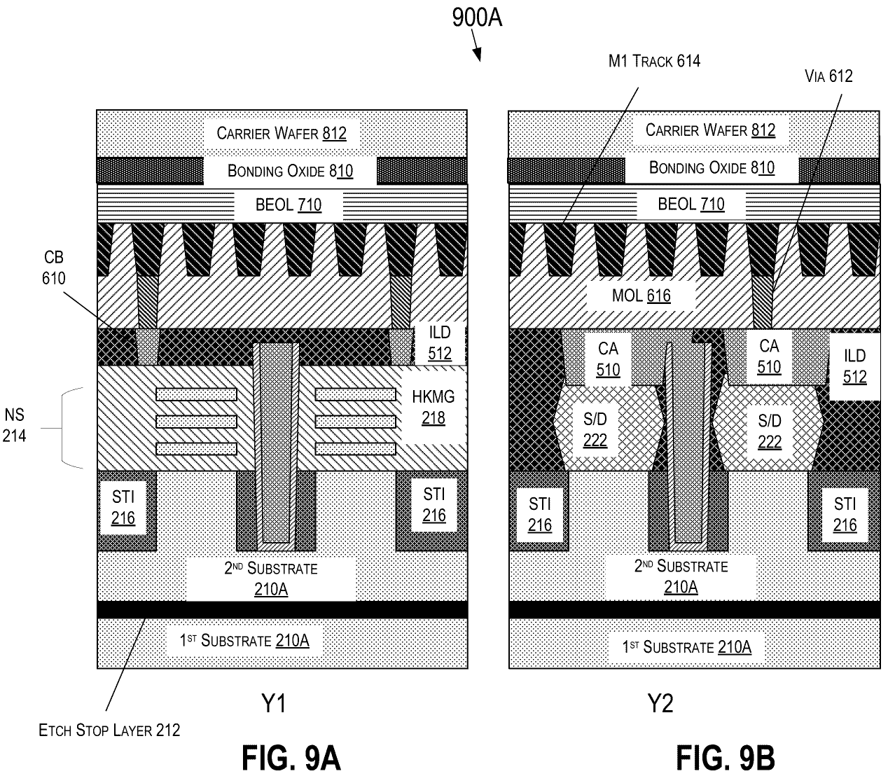

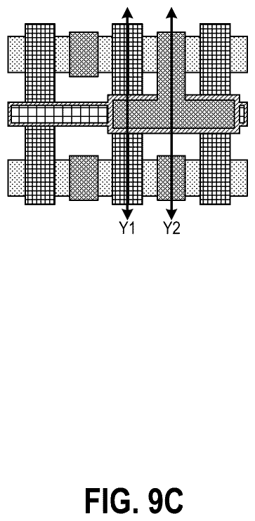

FIGS. 9A-9B illustrate a semiconductor device after the wafer flip and grinding, in accordance with some embodiments. In some embodiments, the logic device 900A is flipped and a backside of the logic device 900A is grinded. A chemical-mechanical polishing process can be performed to remove the contaminants and smoothen the logic device 900A. It should be noted that, for the sake of simplicity, the logic device 900A is not as flipped. FIG. 9C illustrates a top view of the logic device 900A after the wafer flip.

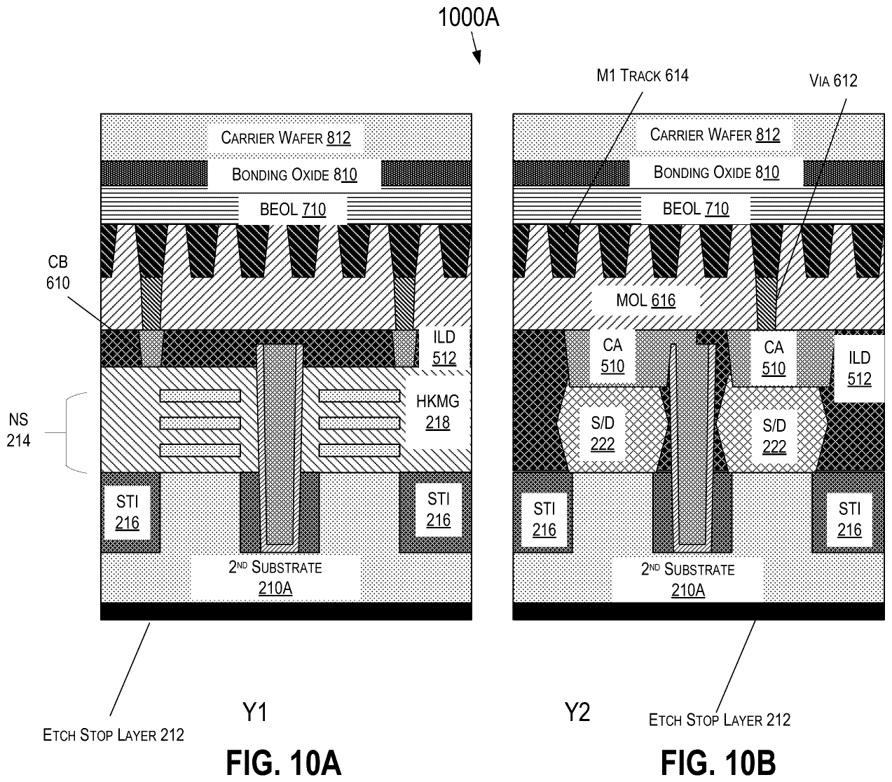

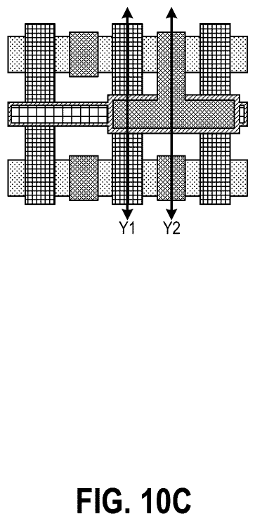

FIGS. 10A-10B illustrate a semiconductor device after the removal of the first substrate, in accordance with some embodiments. In some embodiments, the first substrate is removed. The substrate removal stops at the etch stop layer 212. FIG. 10C illustrates a top view of the logic device 1000A after the removal of the first substrate.

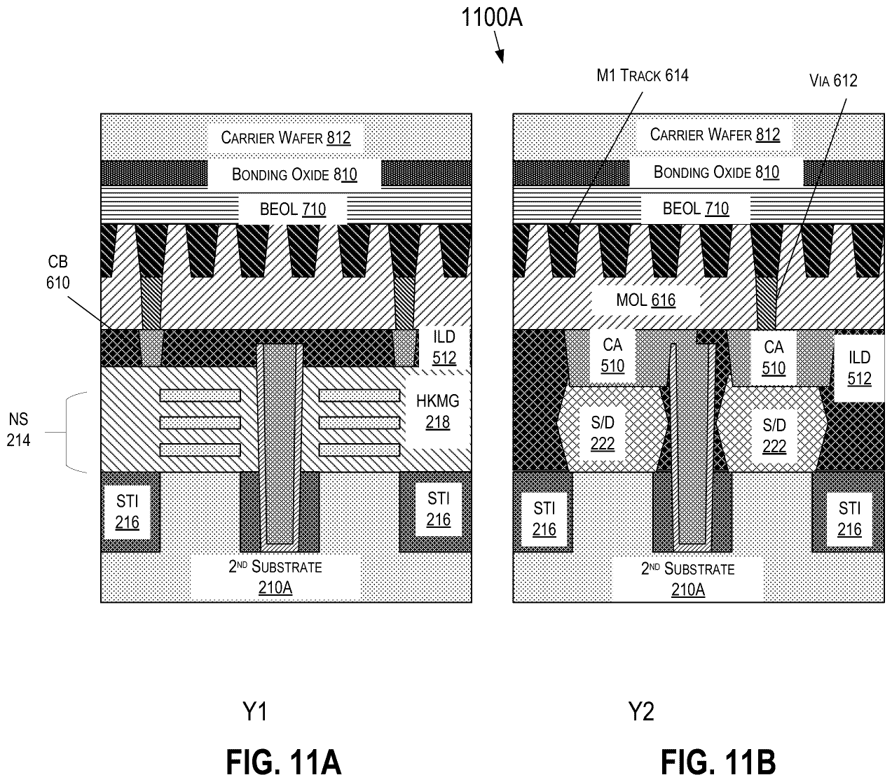

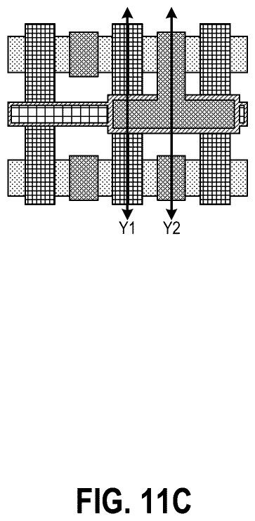

FIGS. 11A-11B illustrate a semiconductor device after the after the removal of the etch stop layer, in accordance with some embodiments. In some embodiments, the etch stop layer is removed. FIG. 11C illustrates a top view of the logic device 1100A after the removal of the etch stop layer.

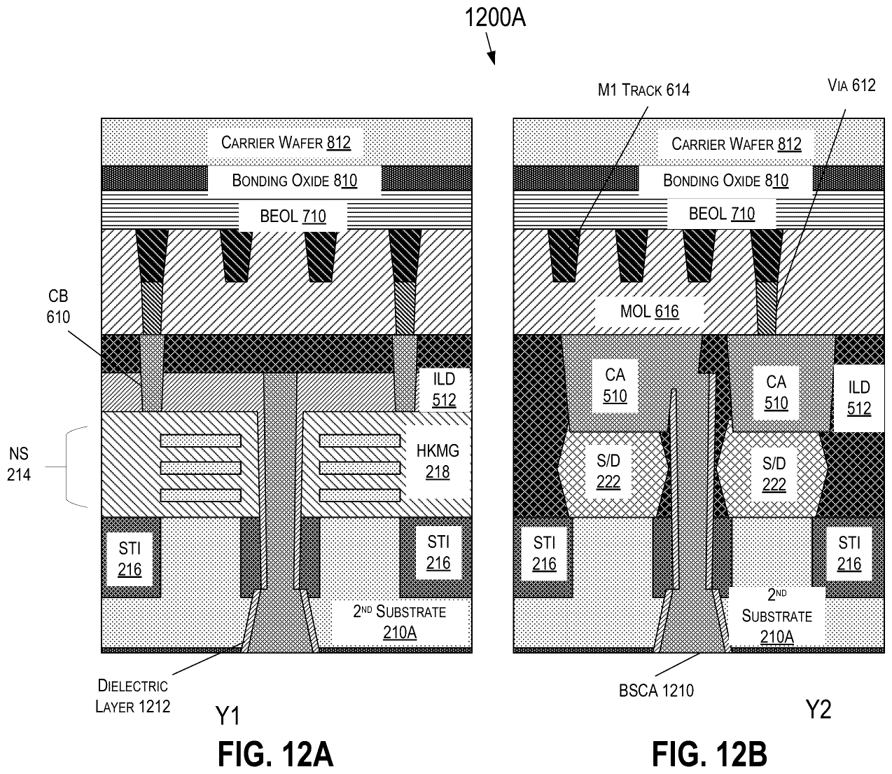

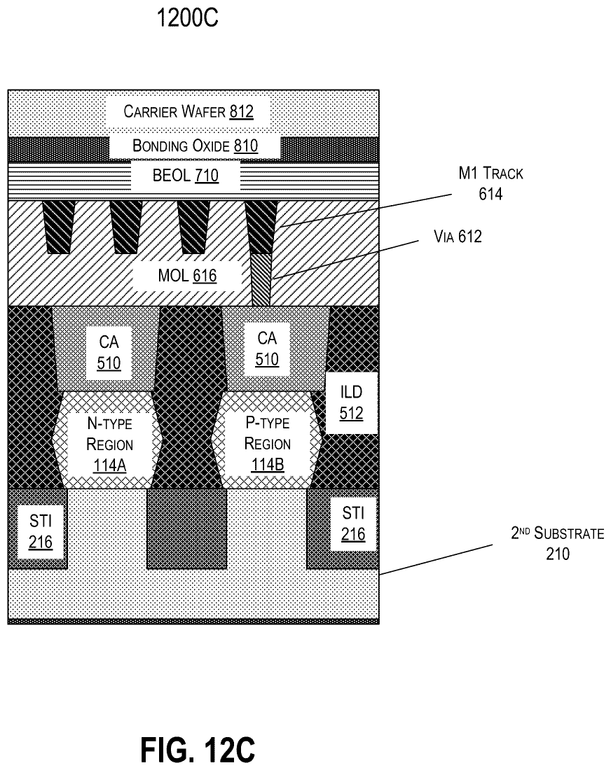

FIGS. 12A-12C illustrate a semiconductor device after the formation of the layer of dielectric layer and the backside contact, in accordance with some embodiments. In some embodiments, the backside contacts, BSCA 1210 is formed to connect the backside of the logic device 1200A to the MOL 616 and the BEOL 710. A dielectric layer 1212 is formed over the sidewalls of the BSCA 1210 to isolate the BSCA 1210 from the second substrate 210B, the STI 260, and the source/drain regions 222. The BSCA 1210 can be surrounded in by the second substrate 210B and the dielectric layer 1212. As can be seen in FIG. 12C, the passive device 1200B does not include BSCA 1210 and the dielectric layer 1212. In some embodiments, a layer of dielectric layer 1214 is formed over the logic device 1200A and the passive device 1200B.

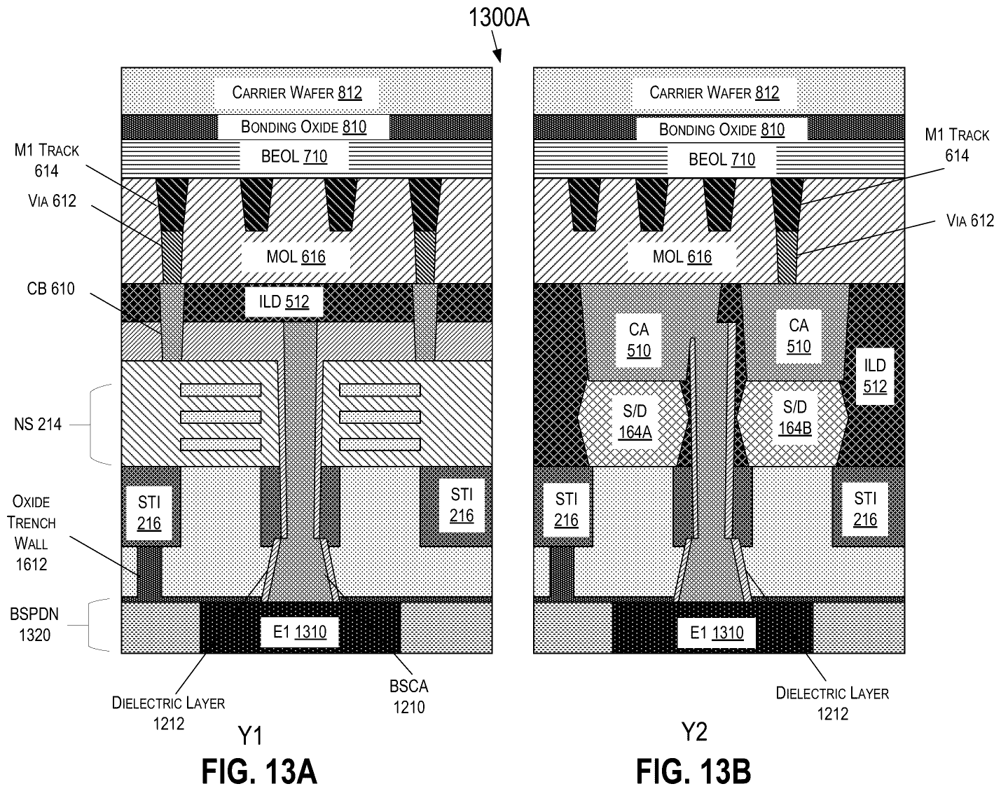

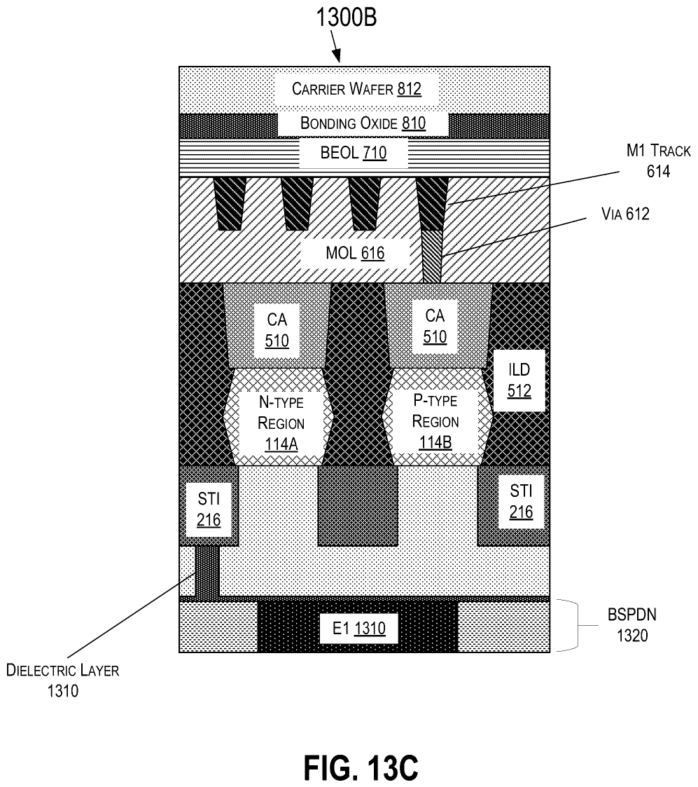

FIGS. 13A-13B illustrate a semiconductor device after the formation of the backside metal lines, in accordance with some embodiments. In some embodiments, a backside power delivery network, BSPDN 1320 in the logic device 1300A and the passive device 1300B. The BSPDN 1320 can connect the semiconductor device to other devices. In some embodiments, a backside metal line, E1 1310 in the BSPDN 1320 in the logic device 1300A and the passive device 1300B.

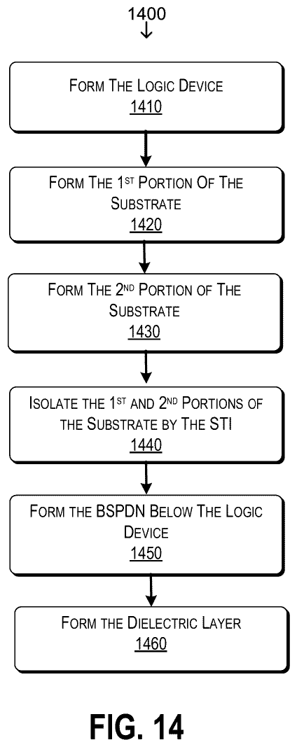

FIG. 14 illustrate a block diagram of a method 1400 for forming the semiconductor device, in accordance with some embodiments. As shown by block 1410, the logic device is formed.

As shown by block 1420, the first portion of the first substrate is formed. The first portion of the first substrate is extended vertically below a first source/drain region.

As shown by block 1430, a second portion of the first substrate is formed. The second portion of the first substrate is extended vertically below a second source/drain region.

As shown by block 1440, the first portion of the first substrate and the second portion of the first substrate are isolated by a first STI.

As shown by block 1450, a BSPDN is formed below the logic device.

As shown by block 1460, a dielectric layer is formed over the sidewalls of a backside contact.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a logic device comprising:
a first portion of a first substrate extending vertically below a first source/drain region;
a second portion of the first substrate extending vertically below a second source/drain region;
a first shallow trench isolation (STI) extending vertically and isolating the first portion of the first substrate and the second portion of the first substrate;
a backside power delivery network (BSPDN) below the logic device; and
a first dielectric layer extending vertically through sidewalls of a backside contact, wherein: the first dielectric layer isolates the backside contact from the first portion of the first substrate and the second portion of the first substrate.

2. The semiconductor device of claim 1, wherein:
the backside contact is located between the first portion of the first substrate and the second portion of the first substrate, and
the backside contact electrically connects a frontside of the logic device to a backside of the logic device.

3. The semiconductor device of claim 1, wherein the first dielectric layer isolates the backside contact from direct contact with the first source/drain region and the second source/drain region.

4. The semiconductor device of claim 1, wherein the first dielectric layer isolates the backside contact from contact with the first STI.

5. The semiconductor device of claim 1, further comprising:
a passive device comprising:
a first portion of a second substrate extending vertically below an N-type doped region;
a second portion of the second substrate extending vertically below a P-type doped region;
a third portion of the second substrate extending horizontally and covering a backside of the passive device; and
a second STI extending vertically and isolating the first portion of the second substrate and the second portion of the second substrate.

6. The semiconductor device of claim 5, wherein the first portion of the first substrate, the second portion of the first substrate, the first portion of the second substrate, and the second portion of the second substrate are made of a same material, are coplanar, and have a same height.

7. The semiconductor device of claim 5, wherein the first STI and the second STI are made of a same material and are coplanar and have a same height.

8. The semiconductor device of claim 1, wherein the first portion of the first substrate is an N-type well, and the second portion of the first substrate is a P-type well.

9. A method for fabrication of a semiconductor device, the method comprising:
forming a logic device comprising:
forming a first portion of a first substrate extended vertically below a first source/drain region;
forming a second portion of the first substrate extended vertically below a second source/drain region;
isolating the first portion of the first substrate and the second portion of the first substrate by a first shallow trench isolation (STI);
forming a backside power delivery network (BSPDN) below the logic device;
forming a first dielectric layer extending vertically through sidewalls of a backside contact;
isolating the backside contact from a direct contact with the first portion of the first substrate and the second portion of the first substrate by the first dielectric layer.

10. The method of claim 9, further comprising establishing an electrical connection between a frontside of the logic device to a backside of the logic device by the backside contact, wherein the backside contact is located between the first portion of the first substrate and the second portion of a second substrate.

11. The method of claim 9, further comprising isolating the backside contact from direct contact with the first source/drain region and the second source/drain region via the first dielectric layer.

12. The method of claim 9, further comprising isolating the backside contact from contact with the first STI via the first dielectric layer.

13. The method of claim 9, further comprising:
forming a passive device comprising:
forming a first portion of a second substrate extended vertically below an N-type doped region;
forming a second portion of the second substrate extended vertically below a P-type doped region;
forming a third portion of the second substrate extended horizontally and covering a backside of the passive device; and
isolating the first portion of the second substrate and the second portion of the second substrate by a second STI.

14. The method of claim 13, wherein the first portion of the first substrate, the second portion of the first substrate, the first portion of the second substrate, and the second portion of the second substrate are made of a same material, are coplanar, and have a same height.

15. The method of claim 13, wherein the first STI and the second STI are made of a same material and are coplanar and have a same height.

16. The method of claim 9, wherein the first portion of the first substrate is an N-type well, and the second portion of the first substrate is a P-type well.

17. A semiconductor device, comprising:
a logic device comprising:
a backside contact electrically connecting a frontside of the logic device to a backside of the logic device; and
a dielectric layer over sidewalls of the backside contact, wherein the dielectric layer isolates the backside contact from direct contact with a first source/drain region, a second source/drain region, a first shallow trench isolation (STI), and a first substrate of the logic device, and
a passive device formed over a second substrate, wherein the first substrate and the second substrate are coplanar.

18. The semiconductor device of claim 17, wherein the logic device further comprises:
a first portion of the first substrate extending vertically below the? first source/drain region;
a second portion of the first substrate extending vertically below the second source/drain;
region; and
a backside power delivery network (BSPDN) below the logic device.

19. The semiconductor device of claim 18, wherein the first portion of the first substrate is an N-type well, and the second portion of the first substrate is a P-type well.

20. The semiconductor device of claim 17, wherein the passive device further comprises:
a first portion of the second substrate extending vertically below an N-type doped region;
a second portion of the second substrate extending vertically below a P-type doped region;
a third portion of the second substrate extending horizontally and covering a backside of the passive device; and
a second STI extending vertically and isolating the first portion of the second substrate; and
the second portion of the second substrate.

21. The semiconductor device of claim 20, wherein the first STI and the second STI are made of a same material and are coplanar and have a same height.

22. A method for fabrication of a semiconductor device, the method comprising:
forming a logic device comprising:
establishing an electrical connection between a frontside of the logic device and a backside of the logic device with a backside contact; and
forming a dielectric layer over sidewalls of the backside contact;
isolating the backside contact from direct contact with a first source/drain region, a second source/drain region, a first shallow trench isolation (STI) and a first substrate via the dielectric layer; and
forming a passive device over a second substrate, wherein the first substrate and the second substrate are coplanar.

23. The method of claim 22, wherein forming the logic device further comprises:
forming a first portion of the first substrate extending vertically below the first source/drain region;
forming a second portion of the first substrate extending vertically below the second source/drain;
region; and
forming a backside power delivery network (BSPDN) below the logic device.

24. The method of claim 22, wherein forming the passive device further comprises:
forming a first portion of the second substrate extending vertically below an N-type doped region;
forming a second portion of the second substrate extending vertically below a P-type doped region;
forming a third portion of the second substrate extending horizontally over the backside of the passive device; and
isolating the first portion of the second substrate and the second portion of the second substrate by a second STI.

25. The method of claim 24, wherein the first STI and the second STI are made of a same material and are coplanar and have a same height.
